(19) United States
(12) Patent Application Publication
(10) Pub. No.: US 2017/0110520 A1
(43) Pub. Date: Apr. 20, 2017

(54) Organic Radiation-Emitting Component

(71) Applicant: OSRAM OLED GmbH, Regensburg (DE)

(72) Inventors: Thomas Wehlus, Lappersdorf (DE); Arne Fleißner, Regensburg (DE); Thilo Reusch, Donaustauf (DE); Daniel Riedel, Regensburg (DE)

(73) Assignees: OSRAM OLED GmbH, Regensburg (DE); OSRAM OLED GmbH, Regensburg (DE)

(21) Appl. No.: 15/127,011

(22) PCT Filed: Mar. 13, 2015
(86) PCT No.: PCT/EP2015/055326

§ 371 Date: Sep. 17, 2016

(30) Foreign Application Priority Data
Mar. 19, 2014 (DE) 10 2014 103 751.0

(51) Int. Cl. H01L 27/32; H01L 51/56

(52) U.S. Cl. CPC H01L 27/3204; H01L 51/56

(57) ABSTRACT

An organic radiation-emitting component and a method for manufacturing an organic radiation-emitting component are disclosed. In an embodiment, the component includes a base substrate and a plurality of light-emitting units disposed on the base substrate, wherein the light-emitting units are arranged laterally offset with respect to one another, wherein the plurality of light-emitting units is divided into light-emitting units of a first type and light-emitting units of a second type, wherein a current flow through the light-emitting units of the first type is directed in an opposite direction to a current flow through the light-emitting units of the second type during operation, and wherein the light-emitting units are grouped in neighboring pairs, each neighboring pair consists of a light-emitting unit of a first type and a light-emitting unit of a second type, both first electrodes or both second electrodes of which are electrically connected to one another.

This patent application is a national phase filing under section 371 of PCT/EP2015/055326, filed Mar. 13, 2015, which claims the priority of German patent application 10 2014 103 751.0, filed Mar. 19, 2014, each of which is incorporated herein by reference in its entirety.

### TECHNICAL FIELD

An organic radiation-emitting component and a method for producing the same are provided.

### BACKGROUND

Radiation-emitting devices, in particular devices comprising organic light-emitting diodes (OLEDs), are suitable as large-area thin light-emitting elements. It is desirable in many applications that electromagnetic radiation is emitted over a most large light-emitting surface. However, there are multiple factors limiting arbitrary scaling of the radiation-emitting devices. For example, high surface resistivity of transparent electrodes has a highly-limiting effect. Without said resistance, the electric supply of large-area organic light-emitting diodes is difficult to achieve without a major voltage drop and an inhomogeneity of the light-emitting diode.

One solution known from the prior art consists in using bus bars on the electrode areas so that the effective conductivity of the electrodes is increased. Another solution consists in achieving the increase of conductivity of the electrode areas by means of thick layers of TCO (Transparent Conductive Oxide) or novel electrode systems such as silver nanowires. However, this solution is comparatively elaborate. According to another approach, a plurality of singularized OLED components is arranged next to one another on an area, said components being electrically connected to one another via external structures. In this case, the cathode of an OLED component is guided onto the anode of the following OLED component. This approach is difficult in terms of process technology since electric connection of the upper electrode of the first OLED component and the lower electrode of the following OLED component needs to be established across two levels of the component. As a result, a series connection of said OLED components requires a three-dimensionally guided and topographically complex current connection.

### SUMMARY OF THE INVENTION

Embodiments provide an organic radiation-emitting component having a large light-emitting surface, which has a most homogenous radiation intensity. Embodiments provide an organic radiation-emitting component in which a plurality of individual radiation-emitting components can be connected to one another without a complex three-dimensional topography.

According to at least one embodiment, an organic radiation-emitting component comprises a base substrate and a plurality of light-emitting units on the base substrate. As used here and in the following, a layer or an element being arranged or applied “on” or “to” another layer or another element relates to a situation where said layer or said element is directly arranged in a direct mechanical and/or electrical contact on the other layer or the other element. It may furthermore relate to a situation where said layer or said element is indirectly arranged on or respectively above the other layer or the other element. In this case, further layers and/or elements may be arranged between one and the other layer. The corresponding applies to the arrangement of a layer or an element “between” two other layers or two other elements.

According to at least one embodiment of the component, it is provided that the light-emitting units are arranged laterally offset to one another and each of the light-emitting units comprises in each case at least one first electrode arranged on the base substrate, at least one second electrode arranged on the first electrode, and at least one organic radiation-emitting layer between the first electrode and the second electrode. The term lateral direction particularly relates to a direction parallel to a main extension plane of the base substrate and/or at least one of the organic radiation-emitting layers. In analogy, vertical direction particularly relates to a direction perpendicular to a main extension plane of the base substrate and/or one of the organic radiation-emitting layers.

According to at least one embodiment of the component, it is provided that the organic radiation-emitting layer is designed to emit electromagnetic radiation during operation of the component. The organic radiation-emitting layer is preferably designed to emit electromagnetic radiation in the visible wavelength range, particularly colored or white light, during operation of the component.

According to at least one embodiment of the component, it is provided that the plurality of light-emitting units is divided into a plurality of light-emitting units of a first type and a plurality of light-emitting units of a second type. Preferably, it is provided that the light-emitting units of the first type and the light-emitting units of the second type are identically constructed or are at least identically constructed except for an inversion (parity reflection). This particularly means that both the light-emitting units of the first type and the light-emitting units of the second type are in each case identically constructed amongst one another and that the light-emitting units of the second type differ from the light-emitting units of the first type at most by their spatial orientation.

According to at least one embodiment of the component, it is provided that during operation, a current flow is directed through the light-emitting units of the first type in an opposite direction to a current flow through the light-emitting units of the second type. The light-emitting units of the first type and the light-emitting units of the second type will be flown through by current in opposite directions during operation of the component. In particular, a current flow through the light-emitting units of the first type may be directed away from the base substrate during operation of the component and a current flow through the light-emitting units of the second type may be directed toward the base substrate. In this case, the first electrode of a light-emitting unit of a first type functions as an anode and the second electrode thereof functions as a cathode. In analogy, the first electrode of a light-emitting unit of the second type functions as a cathode and the second electrode thereof functions as an anode.

According to at least one embodiment of the component, it is provided that neighboring pairs of light-emitting units are provided, each consisting of a light-emitting unit of the first type and a light-emitting unit of the second type, the two first electrodes of which or the two second electrodes of which are electrically connected to one another. Specifically, this means that the first electrode of the light-emitting unit of the first type and the first electrode of the light-emitting unit of the second type can be electrically connected to one another in one neighboring pair. As an alternative, the second electrode of the light-emitting unit of the first type and the second electrode of the light-emitting unit of the second type can be electrically connected to one another in one neighboring pair. Thus, in each case electrodes of both light-emitting units are electrically connected to one another, said electrodes being located on the same side of the organic radiation-emitting layer.

This allows connecting the two light-emitting units of the neighboring pairs in series with respect to one another, without that elaborate wiring across various levels being required. As a result of the fact that the light-emitting units of the first type and the light-emitting units of the second type are flown through by current in opposite directions to one another, they can rather be electrically connected to one another on one level of the component and thus be connected in series, for example on the level of the base substrate area.

The plurality of light-emitting units on the base substrate functions as monolithically integrated pixels that are flown through by current in different directions and that allow for generating a large light-emitting surface without that the limited conductivity of the transparent electrodes or alternatively designed electrode systems affect the homogeneity of the luminance to an excessive extent. It is possible to use pixels of sufficiently small areal dimensions that can be readily supplied with current and build up a light-emitting surface by a suitable series connection, the radiation characteristic of which appears to be uniform to an external observer.

According to at least one embodiment of the component, it is provided that the two first or the two second electrodes of a neighboring pair are formed by a continuous electrode area. This allows for the production of the two electrodes of the neighboring pair by readily providing one individual electrode area.

According to at least one embodiment of the component, it is provided that the organic radiation-emitting layers of the plurality of light-emitting units are designed to generate electromagnetic radiation of overlapping, particularly the same wavelength ranges. However, it may also be advantageous that the organic radiation-emitting layers of the plurality of light-emitting units are designed to generate electromagnetic radiation of wavelength ranges that differ from one another.

According to at least one embodiment of the component, it is provided that the base substrate and the first electrodes of the light-emitting units have a translucent design, so that light generated in the organic radiation-emitting layers can be radiated through the first electrodes and the translucent base substrate. Such an organic radiation-emitting component can also be referred to as a so-called “bottom-emitter”. For example, the base substrate may comprise one or more materials in the type of a layer, a plate, a foil or a laminate, said types being selected from glass, quartz or synthetic material. As used herein, “translucent” relates to a layer that is permeable to visible light. Here, the translucent layer may be transparent, i.e. clearly translucent, or at least partially light-scattering and/or light-absorbing, so that the translucent layer may also be diffuse or milkily translucent. Particularly preferably, a layer referred to as being translucent has a most transparent design so that particularly the absorption of light is as small as possible.

According to another particularly preferred embodiment, the second electrodes of the light-emitting units have a translucent design so that the generated light can be radiated through the second electrodes. Such an organic radiation-emitting component can also be referred to as a so-called “top emitter”. However, the organic radiation-emitting component can also be designed as a “bottom emitter” and as a “top emitter” at the same time.

The electrodes of translucent design may for example comprise a transparent conductive oxide or consist of a transparent conductive oxide. Transparent conductive oxides (TCOs) are transparent, conductive materials, usually metal oxides such as for example zinc oxide, tin oxide, cadmium oxide, titanium oxide, indium oxide or indium tin oxide (ITO).

However, the first or second electrodes may also have a reflective design and, for example, comprise a metal that may be selected from aluminum, barium, indium, silver, gold, magnesium, calcium and lithium as well as compounds, combinations and alloys.

Furthermore, an encapsulation arrangement may be located on top of the electrodes and the plurality of light-emitting units. For example, said encapsulation arrangement may be designed as a glass cover or, preferably, in the type of a thin layer encapsulation.

According to at least one further embodiment of the component, it is provided that the distance between two neighboring light-emitting units to one another is less than 1 mm, in particular less than 0.1 mm. This way, an external observer will not perceive the transitions between the different light-emitting units as disturbing. Furthermore, the spatial dimensions of the light-emitting units defined thereby are sufficiently small so that the light-emitting units can be readily supplied with current and a light-emitting surface can be established by means of a suitable series connection, the radiation characteristic of which appears to be sufficiently uniform to an external observer. In particular, any of the light-emitting units may have a diameter in the lateral direction that is less than 1 mm, particularly less than 0.1 mm. Preferably, it is provided that the light-emitting units are arranged in a two-dimensional, particularly right-angled grid.

According to at least one embodiment of the component, it is provided that the plurality of light-emitting units is arranged in at least one row and that the light-emitting units of the first type and the light-emitting units of the second type are alternately arranged in said row, the first electrodes and the second electrodes of two successive light-emitting units being alternately being electrically connected to one another. For example, the first electrodes of the first and second light-emitting unit, the second electrodes of the second and third light-emitting unit, the first electrodes of the third and fourth light-emitting unit etc. can be electrically connected to one another. This way, it is provided a series connection of the light-emitting units to be achieved in a simple manner.

According to at least one embodiment of the component, it is provided that the plurality of light-emitting units is arranged in at least two parallel rows and that the current flow along a first row is parallel to a current flow along a second row during operation of the component. Preferably, in each case the first and the last light-emitting units of the two rows are electrically connected to one another or set to one potential level each. This way, it is achieved a parallel connection of the first and the second row. This establishes a combined series connection and parallel connection of the light-emitting elements which allows an enlargement of the total light-emitting surface without a related voltage increase.

According to at least one embodiment of the component, it is provided that the plurality of light-emitting units is arranged in at least two parallel rows and that the current flow along a first row is anti-parallel to a current flow along a second row during operation of the component. Preferably, in each case the last light-emitting units of the two rows are electrically connected to one another and the two first light-emitting units are set to different potential levels. This achieves a series connection of the first and second rows.

According to at least one embodiment of the component, it is provided that the light-emitting units are designed as organic light-emitting diodes (OLEDs). Preferably, it is provided that the light-emitting units of the first type and the light-emitting units of the second type are different from one another in terms of their forward direction. For example, the forward direction of the light-emitting units of the first type may be directed away from the base substrate, and the forward direction of the light-emitting units of the second type may be directed toward the base substrate.

Preferably, each light-emitting unit comprises an organic functional layer stack having organic functional layers, which comprises at least one organic radiation-emitting layer. In particular, the light-emitting units may comprise layers that conduct organic holes, in particular hole transport layers, or layers that conduct organic electrons, in particular electron transport layers, which comprise organic polymers, organic oligomers, organic monomers, organic small non-polymer molecules or low-molecular compounds (“small molecules”) or combinations thereof. Preferably, it is provided that both the light-emitting units of the first type and the light-emitting units of the second type comprise the same layer stacks, the light-emitting units of the second type comprising a merely inverted layer sequence when compared to the light-emitting units of the first type.

Preferably, the radiation-emitting layers of the light-emitting units each comprise an electroluminescent material and, particularly preferably, are designed as electroluminescent layer or electroluminescent layer stack. Materials with a radiation emission due to fluorescence or phosphorescence such as polyfluorene, polythiopene or polyphenylene or derivatives, compounds, mixtures or copolymers thereof are suitable as materials. A suitable selection of the materials in the organic radiation-emitting layers may produce monochrome or multi-color or even white light, for example.

According to at least one embodiment of the component, it is provided that the light-emitting units are designed as organic electrochemical cells (OLECs or OLEECs).

OLECs are characterized in that usually merely in each case one individual organic light-emitting layer containing ionic compounds is arranged between their first and second electrodes, compared to the organic functional layer stacks in the related OLEDs. If a direct current is applied to the two electrodes of an OLEC, the positive and negative ions of the ionic compound separate from one another by the electric field produced by the external voltage and travel to one of the electrodes depending on the respective charge thereof. Thus, an excess of positively charged ions of the ionic compound (cations) develops on the electrode contacted with the low electric potential, and an excess of negatively charged ions (anions) develops on the electrode (anode) contacted with the higher electric potential. The excess of ions in the region of the respective electrode enables injection of charge carriers (electrons of the cathode, defect electrons or holes of the anode). This ensues either by tunnel injection due to the formation of a pronounced space-charge region or by doping the organic semi-conductor in the region of the electrodes with the ions (n-doped at the cathode, p-doped at the anode) so that a similar situation as with the multilayer OLEDs having doped injection layers is established. Thus, an OLEC is not a diode and does not have a predefined conduction direction, which is why it may basically be operated in both directions; there is no predefinition as to which of the electrodes functions as an anode or cathode, respectively. When compared to the related OLEDs, OLECs provide the advantage of a greater tolerance in layer thickness, thereby allowing for the application of less precise methods in production. Furthermore, OLECs can be produced without vacuum conditions.

One method for producing an organic radiation-emitting component comprises the following method steps: providing a base substrate and forming a plurality of light-emitting units on said base substrate. The light-emitting units have the structure as described above and are connected to one another.

According to at least one embodiment of the method, it is provided that organic functional layer stacks are formed on sub-regions of electrode areas formed on the base substrate and subsequently organic functional layer stacks with an inverse layer sequence are applied to the still exposed regions of the electrode areas (or more generally to exposed regions of the electrode areas or at least on parts thereof). Here, the organic functional layer stacks may extend beyond the sub-regions of the electrode areas and protrude from the electrode areas laterally, for example.

According to at least one embodiment of the method, it is provided that organic functional layer stacks are formed on sub-regions of electrode areas formed on the base substrate and a congruent structure formed on the covering substrate is applied to the structure arranged on the base substrate in an inverted manner, so that the organic functional layer stacks get into contact with the exposed regions of the electrode areas. Just as well, the organic functional layer stacks may extend beyond the sub-regions of the electrode areas and protrude laterally from the electrode areas, for example.

According to at least one embodiment of the method, it is provided that a large-area electrode area and a large-area organic light-emitting layer are formed on the base substrate and subsequently structuring of the large-area electrode area and of the light-emitting layer ensues so that parts of the light-emitting units are formed.

According to at least one embodiment of the method, it is provided that the base substrate having electrode areas formed thereon and a plurality of organic light-emitting layers formed thereon as well as a covering substrate with electrode areas formed thereon are provided and subsequently base substrate and covering substrate are fixed over one another.

### BRIEF DESCRIPTION OF THE DRAWINGS

Further advantages, advantageous embodiments and developments can be taken from the exemplary embodiments described below in conjunction with the Figures.

The Figures show in:

FIG. 1 a schematic illustration of an organic light-emitting component according to a first exemplary embodiment,

FIGS. 2 and 3 schematic illustrations of a method for producing an organic radiation-emitting component according to various exemplary embodiments,

FIGS. 4 to 6 schematic illustrations of an organic light-emitting component according to various exemplary embodiments in a plan view,

FIG. 7 a schematic illustration of an organic light-emitting component according to a further exemplary embodiment, and

FIGS. 8 to 10 schematic illustrations of a method for producing an organic radiation-emitting component according to various exemplary embodiments.

In the exemplary embodiments and Figures, like, similar or equivalent elements may each be indicated with the same reference numerals. The illustrated elements and dimensional relations amongst one another are not to scale, individual elements such as layers, components, elements or regions may rather be illustrated in an exaggerated size for a better understanding and/or illustration.

### DETAILED DESCRIPTION OF ILLUSTRATIVE EMBODIMENTS

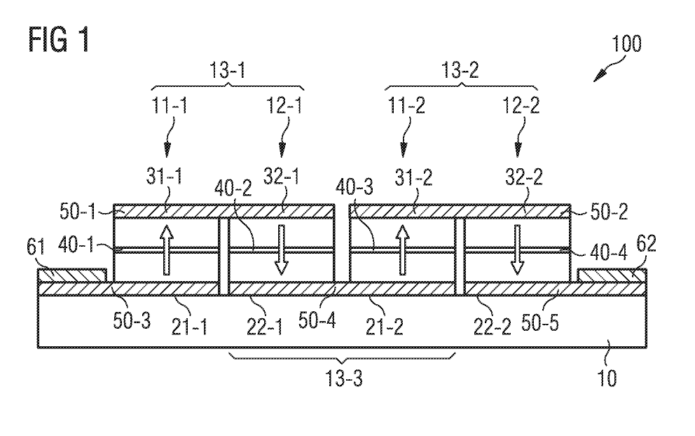

FIG. 1 shows a schematic illustration of an organic radiation-emitting component according to a first exemplary embodiment. The organic radiation-emitting component generally indicated by 100 comprises a transparent base substrate 10, two light-emitting units of a first type 11-1, 11-2 as well as two light-emitting units of the second type 12-1, 12-2 being arranged thereon. Each of the light-emitting units 11-1, 12-1, 11-2, 12-2 comprises in each case one first electrode 21-1, 22-1, 21-2, 22-2 arranged on the base substrate, one second electrode 31-1, 32-1, 31-2, 32-2 arranged on the first electrode, and an organic radiation-emitting layer 40-1, 40-2, 40-3, 40-4 that is arranged between the respective two electrodes. The light-emitting units 11-1, 12-1, 11-2, 12-2 are configured or designed as OLEDs, each comprising an organic functional layer stack between the first and second electrodes. The light-emitting units of the second type 12-1, 12-2 have an inverted layer sequence when compared to the light-emitting units of the first type 11-1, 11-2. Apart from that, the OLEDs 11-1, 12-1, 11-2, 12-2 can be considered as being identically constructed. As a result, the conduction direction of the light-emitting units of the first type 11-1, 11-2 is directed away from the base substrate 10 and the conduction direction of the light-emitting units of the second type 12-1, 12-2 is directed toward the base substrate.

In each case two neighboring light-emitting units 11-1, 12-1 or 11-2, 12-2, respectively, form neighboring pairs 13-1, 13-2 of light-emitting units, in which in each case the second electrodes 31-1, 32-1 or 31-2, 32-2, respectively, are formed by a continuous electrode area 50-1, 50-2 and this way are electrically connected to one another. In FIG. 1, the continuous electrode areas 50-1, 50-2, 50-3 are shown in a hatched manner. Furthermore, a third neighboring pair of light-emitting units 13-3 is formed by the two central light-emitting units 12-1, 11-2, where the first electrodes 22-1, 21-2 are formed by a joint continuous electrode area 50-3 and which are electrically connected to one another, as a result.

This way, the four illustrated light-emitting units 11-1, 12-1, 11-2, 12-2 are connected in series, with the electrical connection between two neighboring light-emitting units being effected in one level of the component 100, respectively. If now a voltage is applied to external contacts 61, 62, a current flow through the light-emitting units of the first type 11-1, 11-2 is directed away from the base substrate 10 and a current flow through the light-emitting units of the second type 12-1, 12-2 is directed toward said base substrate 10. Here, the electrode areas 50-1, 50-2, 50-3 each function as both a cathode and an anode. For example, the region of the electrode area 50-1, which forms the second electrode 31-1 of the light-emitting unit 11-1, functions as a cathode and the region forming the second electrode 32-1 of the light-emitting unit 12-1 functions as an anode.

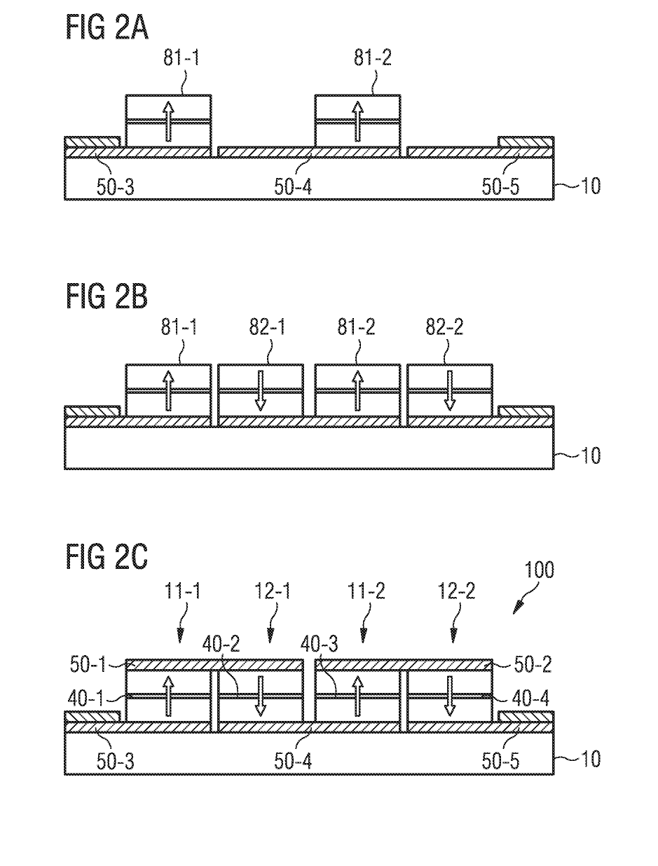

FIG. 2 shows a schematic illustration of a method for producing an organic radiation-emitting component according to a first exemplary embodiment. First, the electrode areas 50-3, 50-4, 50-5 are formed on the base substrate 10. After that, organic functional layer stacks 81-1, 81-2 are formed on sub-regions of the electrode areas 50-3, 50-4, 50-5. The organic functional layer stacks 81-1, 81-2 are formed by vapor (phase) deposition, preferably by physical vapor deposition. This method step is shown in FIG. 2A.

In a subsequent method step shown in FIG. 2B, organic functional layer stacks are applied to still exposed regions of the electrode area 50-3, 50-4, 50-5 with an inverse layer sequence 82-1, 82-2. Finally, the electrode areas 50-1, 50-2 are formed, which face away from the base substrate 10 when viewed from the organic light-emitting layers 40-1, 40-2, 40-3, 40-4 (FIG. 2c).

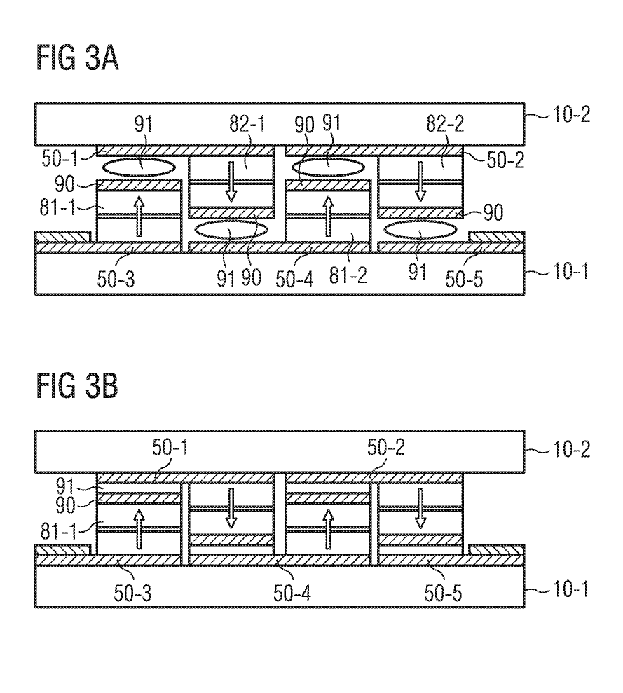

FIG. 3 shows a schematic illustration of a method for producing an organic, radiation-emitting component according to another exemplary embodiment. Similar to the manufacturing method according to the first exemplary embodiment, organic functional layer stacks 81-1, 81-2, which form parts of the light-emitting units of the first type to be produced, are formed on the electrode areas 50-3, 50-4, 50-5 and indirectly on the base substrate 10-1. Further, auxiliary electrodes 90 are formed on the sides of the layer stacks 81-1, 81-2 facing away from the electrode areas 50-3, 50-3, 50-5. As illustrated in FIG. 3A, a congruent structure which is arranged on a covering substrate 10-2 and which is merely inverted is applied on the structure arranged on the base substrate 10-1 in such a way that the organic function functional layer stacks 81-1, 82-1, 81-2, 82-2 get into contact with the exposed regions of the electrode areas 50-1, 50-2, 50-3, 50-4, 50-5 via the auxiliary electrodes 90. Here, a conductive adhesive 91 is used for fixing. FIG. 3B shows the structure connected in said fashion and which represents an organic radiation-emitting component according to a further embodiment.

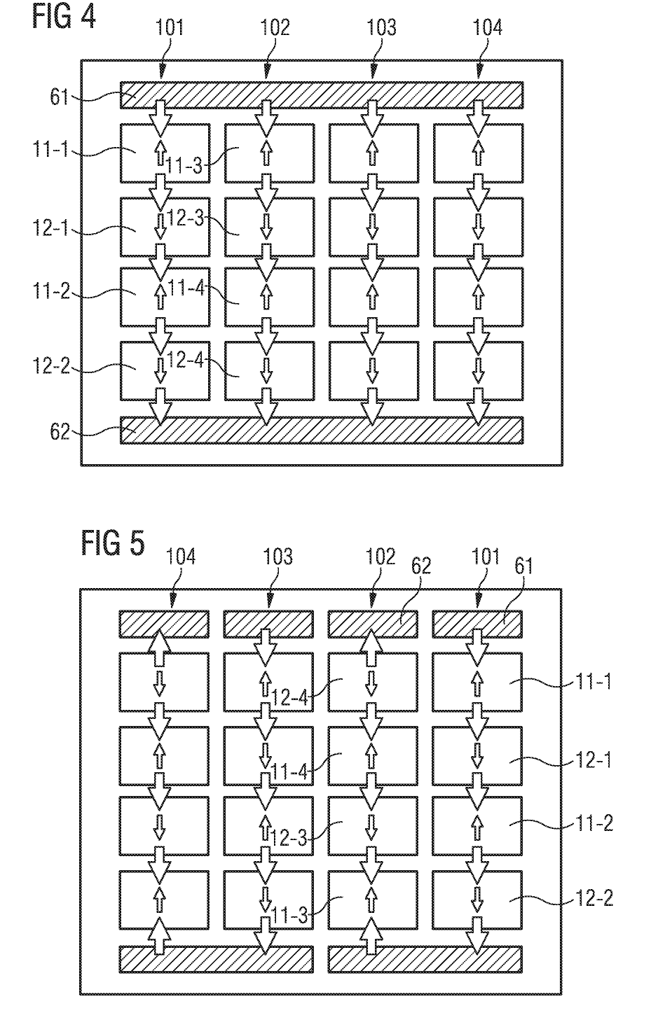

FIG. 4 shows a schematic illustration of an organic radiation-emitting component according to another exemplary embodiment in a plan view. Here, the light-emitting units 11-1, 12-1, 11-2, 12-2 are arranged in four parallel rows 101, 102, 103, 104. Each of these rows consists of alternately arranged light-emitting units of the first type or the second type, respectively, in analogy to the arrangement shown in FIG. 1. The thin arrows shown in FIG. 4 indicate the current flow in a vertical direction inside the light-emitting units, similar to the arrows illustrated in FIG. 1. The thick arrows indicate the current flow in a lateral direction between neighboring light-emitting units. As can be seen in FIG. 4, the current flow is directed along the first row 101 parallel to the current flow along the second row 102. Correspondingly, this applies to the third row 103 and fourth row 104. The in each case first and last light-emitting units of the two rows 101, 102 (the light-emitting units 11-1, 11-3 or 12-2, 12-4) are electrically connected to the contacts 61 or 62, respectively. This way, the first row 101 and the second row 102 are connected in parallel with respect to one another.

FIG. 5 shows a schematic illustration of an organic, radiation-emitting component according to a further exemplary embodiment in a plan view. In contrast to the exemplary embodiment shown in FIG. 4, the lateral current flow along the first row 101 is anti-parallel to the current flow along the second row 102 during operation of the component. Correspondingly, this is also true for the current flow along the third row 103 and the fourth row 104. In contrast to the exemplary embodiment shown in FIG. 4, neighboring light-emitting units of two neighboring rows do not have the same current direction but opposite vertical current directions. The two last light-emitting units of the two rows 101, 102 (corresponding to the light-emitting units 11-3 and 12-2) are electrically connected to one another, while the first two light-emitting units (corresponding to the light-emitting units 11-1 and 12-4) are set to different potential levels using contacts 61, 62. As a result, the first row 101 and the second row 102 are connected in series.

FIG. 6 shows a schematic illustration of an organic radiation-emitting component according to a further exemplary embodiment in a plan view. In contrast to the preceding exemplary embodiments in FIG. 4 and FIG. 5, only the first row 101 and the third row 103 are connected to contact 61 and only the second row 102 and the fourth row 104 are connected to the second contact 62. As illustrated in the exemplary embodiment illustrated in FIG. 5, neighboring light-emitting units of two neighboring rows have opposite vertical current directions. Even wiring along the rows is equal to the wiring of the exemplary embodiment illustrated in FIG. 5. Further, additional connections are provided between light-emitting units of neighboring rows, respectively, through which a current flow can be established between neighboring rows by means of said connections. Any of said connections can be formed between electrodes on the same level of the component, for example, in the present case between the second electrodes of the neighboring light-emitting units.

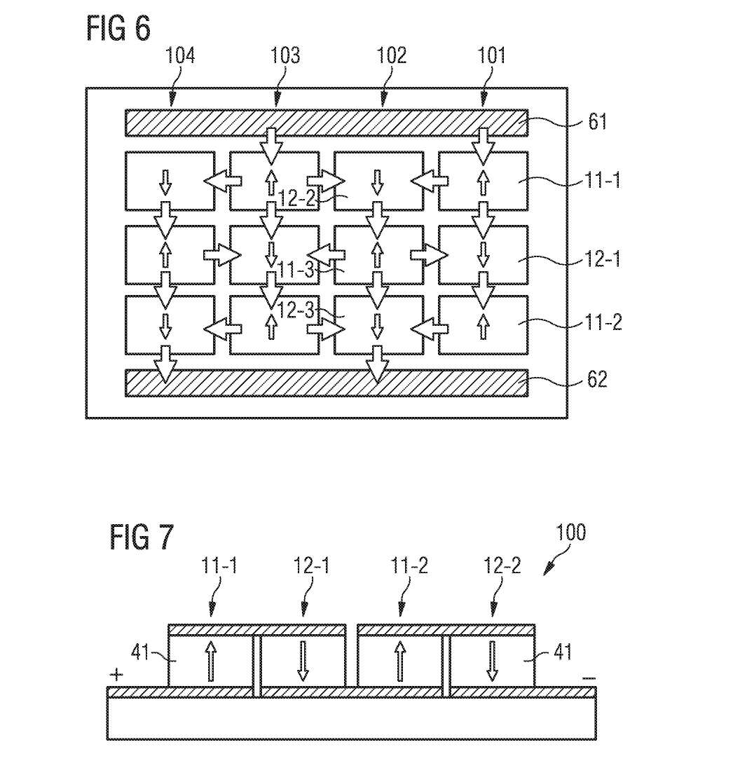

FIG. 7 shows a schematic illustration of an organic radiation-emitting component according to a further exemplary embodiment. In contrast to the exemplary embodiment shown in FIG. 1, the light-emitting units 11-1, 12-1, 11-2, 12-2 are not designed as OLEDs, but designed as OLECs, and merely comprise in each case one individual organic light-emitting layer 41 without predefined conduction direction. Only after application of an external voltage, the p-doping and n-doping required for the light emission is established in the light-emitting layer 41 and defines the directions of the current flow indicated in FIG. 7. Just as well, the component can be operated with a reversed voltage.

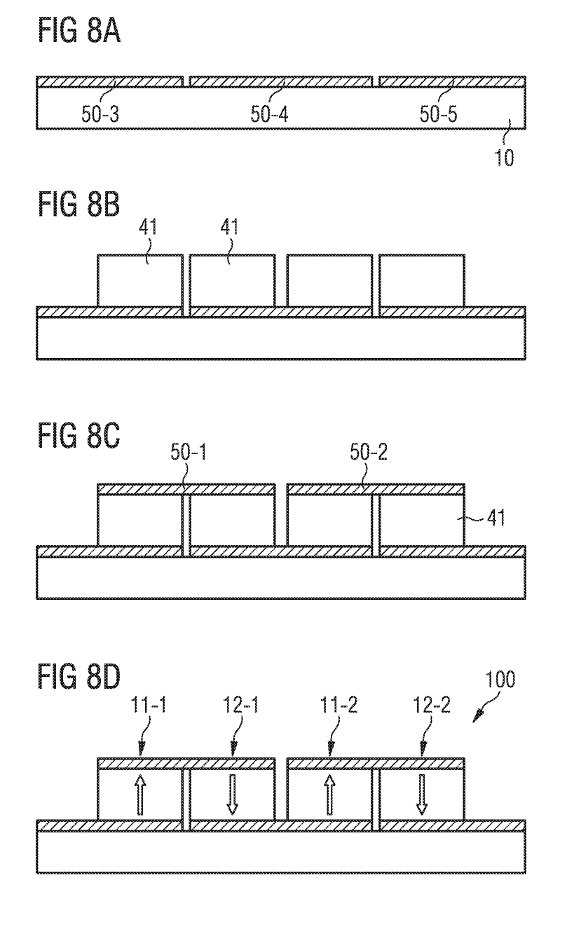

FIG. 8 shows a method for producing of the component shown in FIG. 7 according to a further exemplary embodiment. Similar to the manufacturing method shown in FIG. 2, first a base substrate 10 with electrode areas 50-3, 50-4, 50-5 formed thereon is provided (FIG. 8A). In the subsequent method step shown in FIG. 8B, the organic light-emitting layers 41 are formed. However, since a configuration of layer stacks having an opposed layer sequence as in FIG. 2 is not required, the organic light-emitting layers 41 can be formed simultaneously, i.e. in a single method step. Subsequently, as illustrated in FIG. 8C, the electrode areas 50-1, 50-2, are applied to the side of the organic light emitting layer 41 facing away from the substrate 10. FIG. 8D shows the finished component 100.

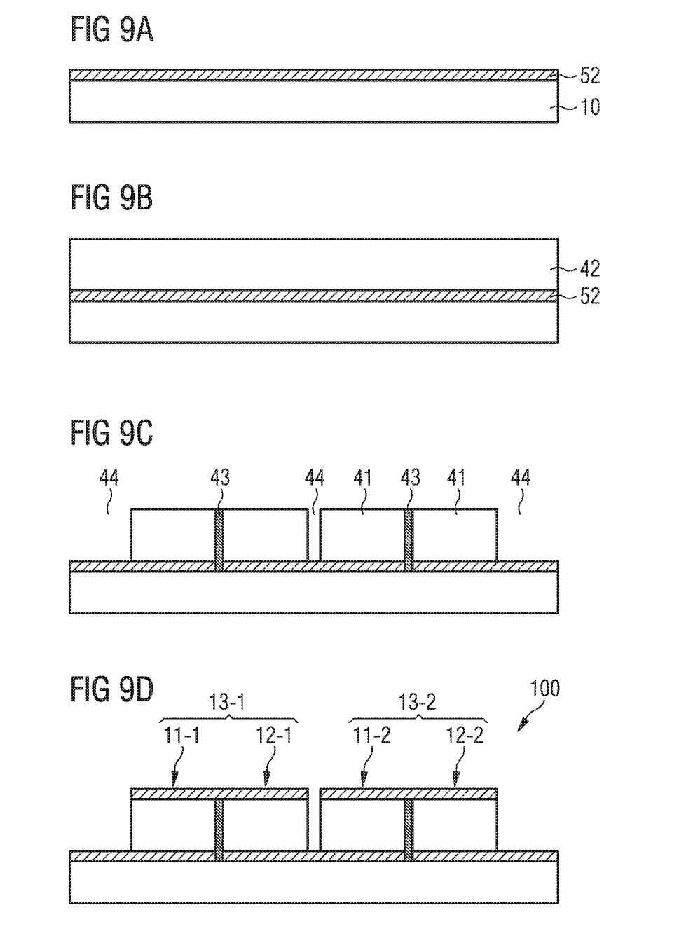

FIG. 9 shows a method for producing an organic radiation-emitting component according to a further embodiment. The present exemplary embodiment makes use of the fact that the light-emitting units 11-1, 12-1, 11-2, 12-2 are identically constructed and do not arise by inversion. Thus, the light-emitting units of the first type or the second type, respectively, do not have to be formed separately, it is rather sufficient to form them by structuring of uniformly-constructed layers.

Specifically, first a large-area electrode area 52 is formed on the base substrate 10 (FIG. 9A). In the subsequent method step shown in FIG. 9B, a large-area organic light-emitting layer 42 is applied to the large-area electrode area 52. As illustrated in FIG. 9C, said step is followed by a restructuration, for example by laser ablation. Herein, the layers 52, 42 shown in FIG. 9B are separated along predetermined patterns and the exposed regions emerging thereby are filled with an electric insulator 43, for example by using an ink jet. Furthermore, the large-area light-emitting layer 42 shown in FIG. 9 is removed in sub-regions 44 in such a way that the underlying large-area electrode area 52 is exposed. This way, contact faces develop on the edges of the component. This will also result in the separation of neighboring pairs of light-emitting units to be formed. As illustrated in FIG. 9D, finally electrode areas 50-1, 50-2 are formed on the neighboring pairs 13-1, 13-2 of light-emitting units developing thereby.

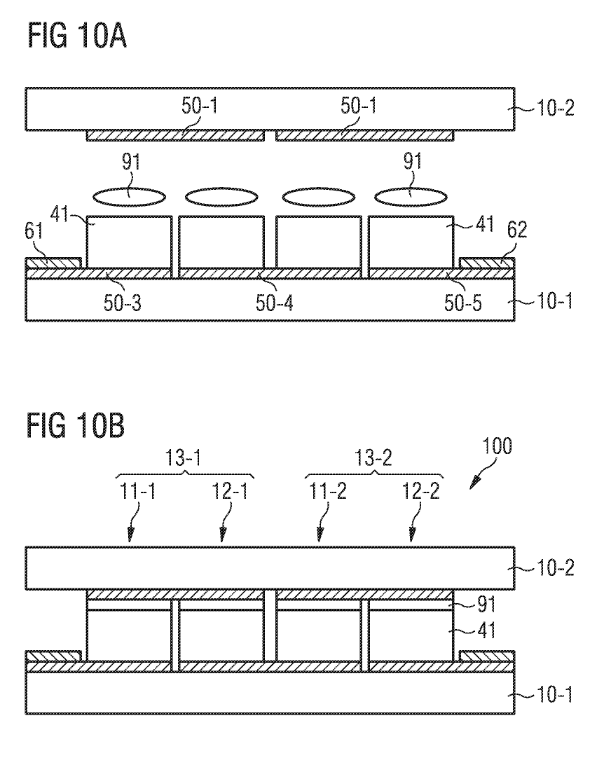

FIG. 10 shows a method for producing of the component shown in FIG. 7 according to a further exemplary embodiment. Here, a base substrate 10-1 with electrode areas 50-3, 50-4, 50-5 arranged thereon is provided, contacts 61, 62 as well as a plurality of organic light-emitting layers 41 being formed on said areas. Furthermore, a covering substrate 10-2 with electrode areas 50-1, 50-2 formed thereon is provided, which is fixed to the base substrate 10-1 using a conductive adhesive 91 in such a way that the component 100 shown in FIG. 10B develops.

The invention is not limited by the description in conjunction with the exemplary embodiments. The invention rather comprises any new feature as well as any combination of features, which particularly includes any combination of features in the patent claims, even if said feature or said combination is not explicitly specified in the patent claims or the exemplary embodiments.

1-14. (canceled)

15. An organic radiation-emitting component comprising:
a base substrate; and
a plurality of light-emitting units disposed on the base substrate,
wherein the light-emitting units are arranged laterally offset with respect to one another, and each of the light-emitting units comprises at least one first electrode arranged on the base substrate, at least one second electrode arranged on the first electrode, and at least one organic radiation-emitting layer arranged between the first electrode and the second electrode,
wherein the organic radiation-emitting layer is designed to emit electromagnetic radiation during operation of the component,
wherein the plurality of light-emitting units is divided into a plurality of light-emitting units of a first type and a plurality of light-emitting units of a second type,
wherein a current flow through the light-emitting units of the first type is directed in an opposite direction to a current flow through the light-emitting units of the second type during the operation of the component, and
wherein the light-emitting units comprise neighboring pairs, each neighboring pair consists of a light-emitting unit of a first type and a light-emitting unit of a second type, both first electrodes or both second electrodes of which are electrically connected to one another.

16. The component according to claim 15, wherein the two first or the two second electrodes of a neighboring pair are formed by a continuous electrode area.

17. The component according to claim 15, wherein the light-emitting units of the first type and the light-emitting units of the second type are identically constructed at least except for an inversion.

18. The component according to claim 15, wherein a distance of each two neighboring light-emitting units to one another is less than 1 mm.

19. The component according to claim 15, wherein the plurality of light-emitting units is arranged in at least one row and the light-emitting units of the first type and the light-emitting units of the second type are arranged alternately in the row, wherein alternately the first electrodes and second electrodes of two successive light-emitting units are electrically connected to one another.

20. The component according to claim 15, wherein the plurality of light-emitting units is arranged in at least two parallel rows and the current flow along a first row is parallel or antiparallel to the current flow along a second row during the operation of the component.

21. The component according to claim 15, wherein the light-emitting units are organic light-emitting diodes.

22. The component according to claim 15, wherein the light-emitting units are designed to generate electromagnetic radiation of overlapping wavelength ranges.

23. The component according to claim 15, wherein the first electrodes or the second electrodes are translucent.

24. The component according to claim 15, wherein the light-emitting units are light-emitting organic electrochemical cells.

25. A method for producing an organic radiation-emitting component, the method comprising:
providing a base substrate; and
forming a plurality of light-emitting units on the base substrate,
wherein the light-emitting units are arranged laterally offset with respect to one another, and each of the light-emitting units comprises at least one first electrode arranged on the base substrate, at least one second electrode arranged on the first electrode, and at least one organic radiation-emitting layer arranged between the first electrode and the second electrode,
wherein the organic radiation-emitting layer is designed to emit electromagnetic radiation during operation of the component,
wherein the plurality of light-emitting units is divided into a plurality of light-emitting units of a first type and a plurality of light-emitting units of a second type such that a current flows through the light-emitting units of the first type in one direction and the current flows in another opposite direction through the light-emitting units of the second type during the operation of the component, and
wherein the light-emitting units comprise neighboring pairs, each neighboring pair consists of a light-emitting unit of a first type and a light-emitting unit of a second type, both first electrodes or both second electrodes of which are electrically connected to one another.

26. The method according to claim 25, wherein organic functional layer stacks are formed on sub-regions of electrode areas formed on the base substrate and subsequently organic functional layer stacks with a reverse layer sequence are applied to exposed regions of the electrode areas.

27. The method according to claim 25, wherein organic functional layer stacks are formed on sub-regions of electrode areas formed on the base substrate and a congruent structure formed on a covering substrate is applied to the structure arranged on the base substrate in an inverted manner so that the organic functional layer stacks get into contact with exposed regions of the electrode areas.

28. The method according to claim 25, wherein a large-area electrode area and a large-area organic light-emitting layer are formed on the base substrate, and wherein the large-area electrode area of the large-area organic light-emitting layer is subsequently structured so that parts of the light-emitting units are formed.

29. The method according to claim 25, wherein the base substrate with electrode areas formed thereon and a plurality of organic light-emitting layers formed thereon as well as a covering substrate with electrode areas formed thereon are provided and, subsequently, the base substrate and covering substrate are fixed one over the other.

30. The method according to claim 25, wherein joint electrode areas forming the two first or second electrodes, respectively, are arranged on opposite sides of the organic radiation-emitting layer.

31. The method according to claim 25, wherein the light-emitting units are light-emitting organic electrochemical cells, wherein the method comprises a large-area electrode area and a large-area organic light-emitting layer are formed on the base substrate, and wherein the large-area electrode area of the large-area organic light-emitting layer is subsequently structured so that parts of the light-emitting units are formed.

32. The method according to claim 25, wherein the light-emitting units are light-emitting organic electrochemical cells, wherein the method comprises the base substrate with electrode areas formed thereon and a plurality of organic light-emitting layers formed thereon as well as a covering substrate with electrode areas formed thereon are provided and, subsequently, base substrate and covering substrate are fixed one over the other, and wherein the organic light-emitting layers are formed in a single method step.

33. An organic radiation-emitting component comprising:
a base substrate; and
a plurality of light-emitting units disposed on the base substrate,
wherein the light-emitting units are arranged laterally offset with respect to one another, and each of the light-emitting units comprises at least one first electrode arranged on the base substrate, at least one second electrode arranged on the first electrode, and at least one organic radiation-emitting layer arranged between the first electrode and the second electrode,
wherein the organic radiation-emitting layer is designed to emit electromagnetic radiation during operation of the component,
wherein the plurality of light-emitting units is divided into a plurality of light-emitting units of a first type and a plurality of light-emitting units of a second type,
wherein a current flow through the light-emitting units of the first type is directed in an opposite direction to a current flow through the light-emitting units of the second type during the operation of the component,
wherein the light-emitting units comprise neighboring pairs, each neighboring pair consists of a light-emitting unit of a first type and a light-emitting unit of a second type, both first electrodes or both second electrodes of which are electrically connected to one another, and
wherein joint electrode areas forming the two first or second electrodes, respectively, are arranged on opposite sides of the organic radiation-emitting layer.

34. The component according to claim 33, wherein the light-emitting units are light-emitting organic electrochemical cells.
